(19) United States
(12) Patent Application Publication
(10) Pub. No.: US 2026/0099643 A1
(43) Pub. Date: Apr. 9, 2026

(54) SYSTEMS AND METHODS FOR GENERATING GEO-REFERENCED AGRICULTURAL MAPS AND/OR FOR PLANNING/MANAGING AGRICULTURAL OPERATIONS BASED ON SUCH MAPS

(71) Applicant: CNH Industrial America LLC, New Holland, PA (US)

(72) Inventors: Robert A. Zemenchik, Fair Oaks, CA (US); Darian E. Landolt, Evanston, IL (US); Michael F. Alfano, Tampa, FL (US)

(21) Appl. No.: 19/244,091

(22) Filed: Jun. 20, 2025

Related U.S. Application Data
(60) Provisional application No. 63/662,728, filed on Jun. 21, 2024.

(51) Int. Cl. G06F 30/20

(52) U.S. Cl. CPC G06F 30/20

(57) ABSTRACT

In one aspect, a computing system is configured to: receive input data associated with producing crops within a field during a crop production cycle; calculate carbon intensity (CI) scores for a plurality of locations within the field based at least in part on the input data; and generate a geospatial CI map based on the calculated CI scores.

### CROSS-REFERENCE TO RELATED APPLICATIONS

The application is based upon and claims the right of priority to U.S. Provisional Patent Application No. 63/662,728, filed Jun. 21, 2024, the disclosure of which is hereby incorporated by reference herein in its entirety for all purposes.

### FIELD OF THE INVENTION

The present disclosure generally relates to agricultural data and associated agricultural operations and, more particularly, to systems and methods for generating geo-referenced agricultural maps (e.g., geospatial carbon intensity maps) and/or for planning/managing agricultural operations based on such maps.

### BACKGROUND OF THE INVENTION

As is generally understood, a carbon intensity score provides a measure of how much carbon-based energy or inputs are used for producing a given amount of crop material (e.g., a bushel of grain). As such, carbon intensity scores take into account various factors, such as fuel consumed during the performance of agricultural operations within a field (e.g., tilling, fertilizing, planting, spraying, harvesting, etc.), the amount of carbon associated with inputs applied to the field (e.g., fertilizers, pesticides, cover crops, etc.), the crop output from the field (e.g., yield), and the like.

For many years, producers have relied primarily on yield maps as the basis for assessing field performance. However, with the emergence of financial incentives that are tied to agricultural carbon offsets (e.g., the amount of carbon captured during crop production that can offset an indirect external carbon release) and carbon insets (e.g., directed changes in carbon capture considered part of the supply chain), producers are seeking more in terms of data for evaluating their crop yield. In this regard, services are currently available that allow a producer to estimate a gross or “whole-field” carbon-related score for a crop originating in their field, which can be aggregated with carbon-related scores for their other fields to generate a “whole carbon” score at the enterprise level. However, such gross carbon-related estimates do not take into account variations in operations, inputs, carbon concentrations, etc. occurring across a field and, thus, do not provide an accurate measurement of the carbon intensity associated with the crop produced within each local section of the field, particularly in large-acre farming. As a result, crop producers are not equipped to take advantage of the crop output deriving from portions of the field associated with lower carbon intensity scores and/or do not have access to sufficiently granular data to make more informed decisions on what types of adjustments can be made to their farming practices, allocation of inputs, and/or equipment to reduce their carbon intensity scores across one or more portions of their field. As the industry transitions to models in which the financial valuation of crops is conducted at least in part on a carbon intensity basis, producers must have access to advanced systems and data for assessing crops produced in their field.

Accordingly, there is a need for systems and methods for generating geo-referenced agricultural maps for a field (e.g., geospatial carbon intensity maps) and/or for planning/managing agricultural operations based on such maps.

### SUMMARY OF THE INVENTION

Aspects and advantages of the technology will be set forth in part in the following description, or may be obvious from the description, or may be learned through practice of the technology.

In one aspect, the present subject matter is directed to a system for generating geo-referenced agricultural maps in accordance with one or more embodiments described herein.

In another aspect, the present subject matter is directed to a method for generating geo-referenced agricultural maps in accordance with one or more embodiments described herein.

In a further aspect, the present subject matter is directed to a system for planning/managing agricultural operations based on a geo-referenced agricultural map in accordance with one or more embodiments described herein.

In one aspect, the present subject matter is directed to a method for planning/managing agricultural operations based on a geo-referenced agricultural map in accordance with one or more embodiments described herein.

In another aspect, the present subject matter is directed to a system for generating geospatial carbon intensity (CI) maps for fields. The system includes a computing system including a processor and memory. The memory stores instructions that, when implemented by the processor, configure the computing system to: receive field data associated with a size or boundaries of a field; receive machine data associated with machine operations during a crop production cycle within the field, the machine operations occurring at least partially within the field; receive field input data associated with inputs within the field during the crop production cycle; receive edaphic data associated with soil within the field; receive crop data associated with crops harvested up to and at the end of the crop production cycle; calculate CI scores for a plurality of locations within the field based at least in part on the field data, the machine data, the field input data, the edaphic data, and the crop data; and generate a geospatial CI map based on the calculated CI scores.

In a further aspect, the present subject matter is directed to a method for generating geospatial carbon intensity (CI) maps for fields. The method includes: receiving, with the computing system, field data associated with a size or boundaries of a field; receiving, with the computing system, machine data associated with machine operations during a crop production cycle within the field, the machine operations occurring at least partially within the field. The method also includes receiving, with the computing system, field input data associated with inputs within the field during the crop production cycle; receiving, with the computing system, edaphic data associated with soil within the field; receiving, with the computing system, crop data associated with crops harvested up to and at the end of the crop production cycle; calculating, with the computing system, CI scores for a plurality of locations within the field based at least in part on the field data, the machine data, the field input data, the edaphic data, and the crop data; and generating, with the computing system, a geospatial CI map based on the calculated CI scores.

In one aspect, the present subject matter is directed to an agricultural system including a computing system including a processor and memory. The memory stores instructions that, when implemented by the processor, configure the computing system to: receive input data associated with producing crops within a field during a crop production cycle; generate one or more geo-referenced agricultural maps based on the input data; and provide outputs related to the data incorporated within the one or more geo-referenced agricultural maps.

In another aspect, the present subject matter is directed to an agricultural method including receiving, with a computing system, input data associated with producing crops within a field during a crop production cycle; generating, with the computing system, one or more geo-referenced agricultural maps based on the input data; and providing, with the computing system, outputs related to the data incorporated within the one or more geo-referenced agricultural maps.

In a further aspect, the present subject matter is directed to an agricultural system including a computing system having a processor and memory. The memory stores instructions that, when implemented by the processor, configure the computing system to: receive input data associated with producing crops within a field during a crop production cycle; calculate carbon intensity (CI) scores for a plurality of locations within the field based at least in part on the input data; and generate a geospatial CI map based on the calculated CI scores.

In another aspect, the present subject matter is directed to a method for generating geospatial carbon intensity (CI) maps for fields. The method includes receiving, a computing system, input data associated with producing crops within a field during a crop production cycle; calculating, with the computing system, carbon intensity (CI) scores for a plurality of locations within the field based at least in part on the input data; and generating, with the computing system, a geospatial CI map based on the calculated CI scores.

These and other features, aspects and advantages of the present technology will become better understood with reference to the following description and appended claims. The accompanying drawings, which are incorporated in and constitute a part of this specification, illustrate embodiments of the technology and, together with the description, serve to explain the principles of the technology.

### BRIEF DESCRIPTION OF THE DRAWINGS

A full and enabling disclosure of the present technology, including the best mode thereof, directed to one of ordinary skill in the art, is set forth in the specification, which makes reference to the appended figures, in which:

FIG. 1 illustrates a schematic view of an agricultural field and various agricultural machines positioned within the field, particularly illustrating exemplary data sources/types that may be utilized to generate a geospatial carbon intensity (CI) map for the field in accordance with aspects of the present subject matter;

FIG. 2 illustrates a schematic view of one embodiment of a system for generating geo-referenced agricultural maps and/or for planning/managing agricultural operations based on such maps is illustrated in accordance with aspects of the present subject matter;

FIG. 3 illustrates an exemplary geospatial CI map in accordance with aspects of the present subject matter; and

FIG. 4 illustrates a flow diagram of one embodiment of a method for generating geo-referenced agricultural maps and/or for planning/managing agricultural operations based on such maps is illustrated in accordance with aspects of the present subject matter.

Repeat use of reference characters in the present specification and drawings is intended to represent the same or analogous features or elements of the present technology.

### DETAILED DESCRIPTION OF THE DRAWINGS

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In general, the present subject matter is directed to systems and methods for generating geo-referenced agricultural maps for fields and/or for planning/managing agricultural operations based on such maps. Specifically, in several embodiments, the disclosed systems and methods may be utilized to generate a geospatial carbon intensity (CI) map for the field as well as to generate/determine one or more recommended courses of actions for improving the CI scores within the field. However, as will be described below, the disclosed systems and methods may also be utilized to generate other types of geo-referenced agricultural maps (e.g., carbon maps, fertilizer usage/efficiency maps, fuel consumption maps, etc.) to allow crop producers to efficiently and effectively plan/manage their agricultural operations.

In several embodiments, the disclosed systems and methods utilize various georeferenced inputs, including field-related, crop-related, machine-related, and/or operation-related inputs, to allow for the generation of a geospatial CI map that provides a CI score at each location (or at various locations) within a field. As a result, a more accurate measure of the CI score for a given amount of harvested crop (e.g., per bushel of grain harvested) may be available to the farmer/producer (hereinafter referred to simply as the “producer”), thereby increasing the potential participation by the producer in the crop production value chain. In particular, with the emergence of financial incentives tied to crop outcomes on a carbon-basis, improved carbon-related data, including a geospatial CI map, will prove extremely valuable to producers, as well as downstream consumers.

It should be appreciated that, in certain instances, the specific input data or dataset used to generate a geospatial CI map (e.g., georeferenced field-related data, crop-related data, machine-related data, and/or operation-related data and/or the like) may vary from country-to-country or jurisdiction-to-jurisdiction based on certain protocols, standards, and/or regulations (hereinafter, generally referred to as “protocols” or “protocol data”) set forth by such jurisdiction/country. Specifically, jurisdictions may have pre-defined protocols that set forth or govern the specific parameters or input data that must be used or accounted for when calculating CI scores. In such instances, the disclosed systems and methods may be configured to utilize or reference such jurisdiction-specific protocol data when generating a geospatial CI map. For instance, when generating a geospatial CI map with a given jurisdiction, a related computing system may be configured to access the protocol data associated with such jurisdiction to identify the specific input data to be used for calculating the CI scores and subsequently perform such calculations and generate the associated CI map in accordance with the jurisdiction-specific protocols or protocol data.

By generating a geospatial CI map for a given field, the disclosed system and method may also allow for enhanced planning/management of agricultural operations. For instance, based on the geospatial CI map, recommendations (or recommended actions) may be provided for adjusting or optimizing machine settings, crop inputs, and/or the like for given sections of a field to provide an improved biological and/or economic response that can reduce the carbon intensity scores associated with such sections of the field. For example, adjustments in seed populations, fertilizer rates, tillage depths, herbicide rates, irrigation scheduling, manure applications, and/or the like may be executed or planned to reduce CI scores within specific sections of the field. Additionally, various technologies may be implemented or adopted in an attempt to reduce CI scores by reducing fuel consumption and/or carbon-related crop inputs, such as the adoption of certain precision farming and/or automation technologies. Moreover, specific farming practices, such as tillage practices, cover crop usage, etc., may be implemented or adjusted across local regions of the field in view of the CI scores contained with the geospatial CI map.

As an example, the disclosed systems and methods may be utilized to produce a field report including various types of georeferenced data for use by a producer. For instance, in addition to a geospatial CI map, the various types/layers of georeferenced data collected and/or used to generate such map may also be individually provided in the form of maps or other visualized data to provide the producer a more complete picture of the various factors contributing to the CI score at different locations throughout the field, such a fuel consumption maps, carbon maps (including mapping bio-reactive and mineral-associated soil carbon sequestration), fertilizer usage/efficiency maps (e.g., nitrogen usage/efficiency maps), soil/nutrient maps, crop quality maps (protein percentage maps), ephemeral or as-applied input maps, and/or the like. Such data/maps may then be analyzed (by the producer or automatically using the disclosed systems/methods) to determine actions or mitigation opportunities for reducing the CI score, either field-wide or within local sections of the field, and/or for optimizing other agricultural parameters/outcomes. As an example, carbon-based prescriptions and/or CI improvement plans may be generated to allow for machine optimization, adjustments in farming practices and/or the like to provide for targeted/tailored CI management.

It should be appreciated that, upon generating a geospatial CI map, one or more subsections or portions of the field may be isolated or selected for management in view of the specific CI scores associated with such subsection(s) or portion(s) of the field and/or in view of any of the underlying data that contributed to the specific CI scores associated with such subsection(s) or portion(s) of the field. As an example, the geospatial CI map (and/or the underlying data) may be analyzed or reviewed to identify focus areas or “areas of interest” (AOIs) within the field to allow location-specific or AOI-specific management to be performed.

Furthermore, the generation and use of geospatial CI maps also allows for improved verification and traceability for both producers and downstream consumers. For instance, producers may utilize the CI maps to allocate crop loads to bins based on CI scores for subsequent blending optimization (e.g., blending of crop having lower CI scores with crop having higher CI scores) and/or market price realization. Moreover, downstream consumers may utilize the geospatial CI maps (and supporting data) to verify the net CI score for a given volume of crop. As an example, digital ledgers (e.g., private ledger blockchain or public ledgers) may be used to provide traceability of the data layers used to compile the CI score for crops harvested within a given section of a field. Such ledgers may allow for the implementation and/or execution of carbon-trading protocol requirements. Ultimately, the disclosed systems and methods will allow producers, as well as consumers throughout the entire food supply chain, to verify and even differentiate among crops or products that achieve minimum standards of carbon impact for any unit of commercial agricultural output.

It should be appreciated that the system outputs described herein may digitally originate in a cloud-based system or within an agricultural machine or vehicle. Additionally, the geo-referenced maps or underlying data may be accessible or transmitted by any device, including any mobile device, desktop computer, and/or network endpoint. The maps may also be created within, or transmitted to, a field vehicle or machine for visualization within the user interface, operating display, or any associated mobile device. The maps and underlying data may also link to any vehicle control system to be used within the field body. For instance, when a machine received a geospatial CI map or any underlying data, it may incorporate it into automatic control system for improved machine operational efficiency, performance optimizations, machine settings, or adjustments.

Additionally, it should be appreciated that the geo-referenced maps or underlying data generated using the disclosed system and method may also be used to manage field inputs (including ephemeral and edaphic-related inputs) within the field boundary. The field inputs may include, but are not limited to, seed type and rate, fertilizer type and rate, insecticide or herbicide type and rate, irrigation rate, or tillage type and rate. Likewise, edaphic-related inputs managed may also include soil amendments and inputs such as manure application, municipal sludge application, liming, biochar application, subsurface drainage system design, and surface topographical management. The geospatial CI map or underlying data can be used to construct prescription maps to interact with a vehicle application control system for either ephemeral or edaphic management within the field boundary.

As will be apparent to those of ordinary skill in the art, numerous advantages/benefits may be derived from the use/execution of the disclosed systems and methods. As an example, advantages/benefits may include, but are not limited to, increased crop values, improved machine productivity and fleet management, improved fertilizer usage efficiency, reduced fuel consumption, lower data collection costs, improved data visualization, lower emissions, enhanced planning/management practices, adaptable crop segmentation practices, enhanced soil analytics, field-based prescriptions, increased nutrient efficiency, improved genetic response, verifiable CI scores, veritable carbon trading, traceability across the supply chain, sustainability, and/or the like.

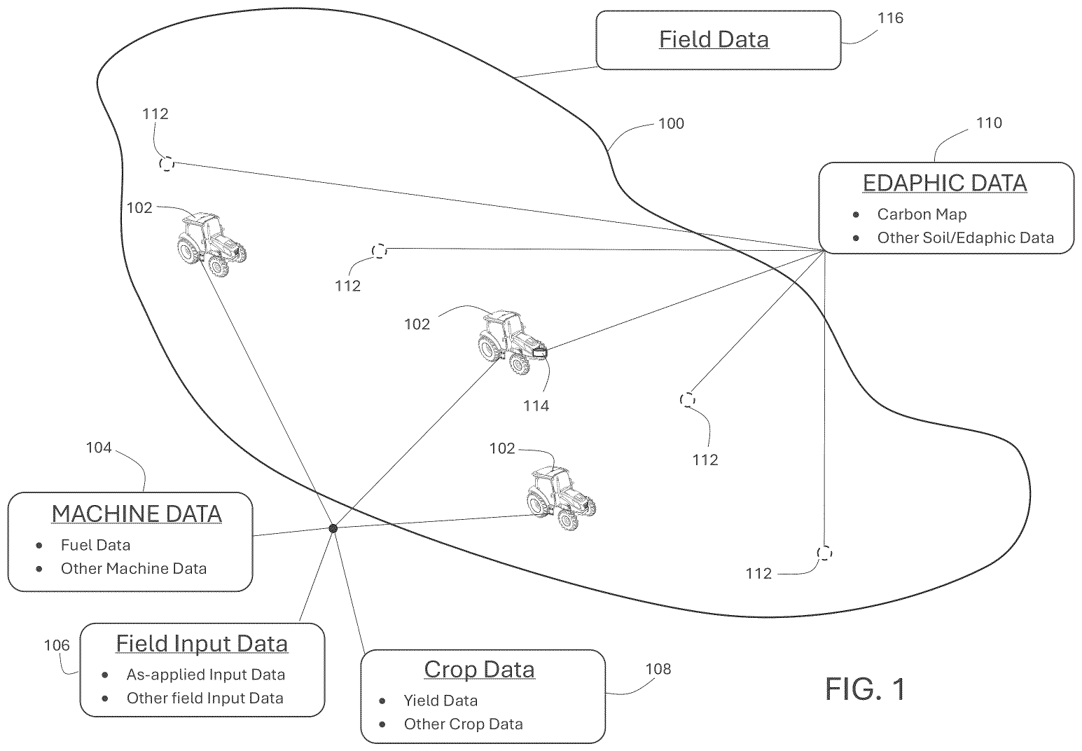

Referring now to the drawings, FIG. 1 illustrates a schematic view of an agricultural field 100 and various agricultural machines 102 positioned within the field 100, particularly illustrating exemplary data sources/types that may be utilized to generate a geospatial carbon intensity (CI) map for the field 100 in accordance with aspects of the present subject matter. As is generally understood, various agricultural operations may be executed within the field 100 across a given crop production cycle (e.g., a 12-month crop production cycle) and various inputs may be applied to or integrated within the field 100 across such crop production cycle. Thus, it should be appreciated that, in several embodiments, relevant data may be collected and/or aggregated across an entire crop production cycle to allow for the generation of a geospatial carbon intensity (CI) map for the field 100.

As shown in FIG. 1, machine data (indicated by box 104) may be collected from the various machines 102 used during the crop production cycle (e.g., since the previous harvest and including the current harvest), such as any agricultural machines used to perform agricultural operations within the field 100 and any other machines used outside the field. For instance, in-field machines may include tractors used to execute various agricultural operations (e.g., tillage, fertilization, planting, seeding, spraying, harvesting, etc.) and dedicated use machines for performing such operations (e.g., combine harvesters, self-propelled sprayers and fertilizer applicators, etc.). Additionally, relevant machines 102 may include grain trucks, service/utility vehicles, pickups, etc. used to perform related operations outside the field, including transporting harvested crops to a repository or storage area (e.g., grain elevator), transporting fertilizer materials, and/or the like. Relevant machines 102 may also include aerial vehicles used for performing certain operations, such as insecticide spraying. In one embodiment, the machine data 104 collected may include fuel data (e.g., fuel consumption data) and other energy-related data associated with the operation of each relevant machine 102 and/or associated with the performance of each related operation. For instance, energy-related data may be collected in relation to the performance of tillage, fertilizer application, planting, spraying, seeding, irrigation, harvesting, and/or the like. In addition, the machine data 104 may include other machine-related data, such as machine identification data (e.g., VIN numbers), time-related machine data (e.g., hours of operation), historical machine data, and/or any other suitable machine data.

Additionally, as shown in FIG. 1, field input data (indicated by box 106) may be collected to account for the various inputs within the field 100 across the applicable crop production cycle, including inputs applied to or integrated within the field 100 and/or any other suitable inputs (e.g. as-applied or crop inputs, edaphic-related inputs, ephemeral-related inputs, etc.). For instance, field inputs may include, but are not limited to, tillage, manure, seeds, lime, fertilizer (macro/micro, chelates), herbicides, inoculants, insecticides, other protection chemicals (e.g., biochar), and/or various other as-applied inputs. Additionally, field input data may include ephemeral-related inputs, such as weather-related inputs and/or the like. In one embodiment, the field input data 106 may include input rates or amounts (e.g., application rates, seed counts, incorporation rates, rainfall amounts, volumes, etc.). In addition, the field input data 106 may include other input-related data, such as the type of tillage operation performed (e.g., primary, secondary, etc.), historical field input data, data related to the carbon inputs associated with fertilizer production (or the production of other inputs), and/or any other suitable field input data.

Moreover, as shown in FIG. 1, crop data (indicated by box 108) may also be collected for the crop harvest up to and at the end of the crop production cycle. For instance, crop data 108 may include yield data for the field. In addition, the crop data 108 may include various other types of data related to the harvested crops, such as moisture data, NDVI data, crop constituent data (e.g., protein percentage, oil percentage, starch percentage, etc.) and/or the like.

It should be appreciated that, in several embodiments, the machine data 104 may be collected from each individual machine 102 (including from sensors associated with each individual machine 102) and stored/organized/aggregated in a given storage location, such as a centralized computing system. Similarly, the field input data 106 may be collected from each machine 102 (including from sensors associated with such machine 102) used in association with one or more of the application/input processes, while the crop data 108 may be collected from each machine 102 (including from sensors associated with such machine 102) used in association with one or more of the harvesting-related operations, with such field/crop data 106, 108 being stored/organized/aggregated in a given storage location, such as a centralized computing system. Additionally, for machines 104 including GPS capabilities or other position-based capabilities (e.g., tractors, harvesters, sprayers, fertilizer applicators, etc.), the data collected by any of such machines 104 (e.g., machine data 102, field input data 104, crop data 106, etc.) may be geo-referenced as it is collected (e.g., by tagging the data with corresponding GPS coordinates or other position data) to allow the data to be correlated to specific locations within the field 100.

Referring still to FIG. 1, the data collected may also include soil or edaphic data (indicated by box 110). In several embodiments, the edaphic data 110 may include data related to the carbon content or concentration within the field 100, including the total carbon content and/or the amounts of inorganic carbon, organic carbon, biologically active carbon, mineral-associated carbon, and/or the like. In addition, the edaphic data 110 collected may include other types of soil-related data, including soil type, soil texture data, soil fertility data (e.g., a total amount of Nitrogen or available amounts of phosphorus and/or potassium), surface drainage data, non-carbon soil constituent data, pH levels, and/or the like.

It should be appreciated that, similar to the various other types of data described above with reference to FIG. 1, the edaphic data 110 may be geo-referenced as it is collected (e.g., by tagging the data with corresponding GPS coordinates or other position data) to allow the data to be correlated to specific locations within the field 100. For instance, the carbon data collected within the field 100 may be geo-referenced to allow a carbon map to be generated that identifies the carbon content at each location (or at various locations) within the field 100.

In one embodiment, the edaphic data 110 may derive from soil testing conducted on a plurality of soil samples or cores (e.g., as indicated by dashed circles 112 in FIG. 1) taken from numerous locations across the field 100. In such an embodiment, the amount of soil cores 112 (and the spacing between the soil cores 112) may be selected to ensure sufficient edaphic data 110 is collected across the field 100. In another embodiment, one or more soil sensors 114 may be used to actively collect the edaphic data 110 at each location (or at various locations) across the field 100. For instance, as shown in FIG. 1, a soil sensor 114 may be mounted to an agricultural machine 102 (e.g., a tractor) to allow the sensor 114 to collect edaphic data 110 as the machine 102 is moved across the field 100 during the performance of an agricultural operation. Alternatively, the soil sensor 114 may be mounted to a machine or vehicle (e.g., an all-terrain vehicle) that is driven across the field 100 for the primary purpose of collecting the edaphic data 110. One example of a suitable sensor assembly that can be used as a soil sensor 114 in accordance with aspects of the present subject matter is described in US2024/0125759 (assigned to GroundTruth Ag Inc.), the disclosure of which is hereby incorporated by reference herein in its entirety for all purposes. Similarly, one example of a commercially available sensor that can be used as a soil sensor 114 in accordance with aspects of the present subject matter includes the GROUNDOWL sensor assembly available from EARTHOPTICS (headquartered in Arlington, VA).

In several embodiments, the edaphic data 110 from the core samples 112 may be used as a ground-truth for calibrating or interpreting the sensor data from the soil sensor 114. For instance, in one embodiment, a number of core samples 112 may be obtained at various locations across the field 100 and separately tested to develop baseline edaphic data for the field 100. This baseline edaphic data may then be used to calibrate the sensor data and/or to train the model used to generate the edaphic data 110 from the sensor data provided by the soil sensor 114. Specifically, in one embodiment, a machine-learned model may be used to determine the edaphic data 110 based on the sensor data derived from the soil sensor 114. In such an embodiment, the baseline edaphic data deriving from the separately tested core samples 112 may be, for example, used as train the machine-learned model.

As shown in FIG. 1, other types of data may also be used for generating a geospatial CI map for the field 100. For instance, field data (indicated by box 116), such as the boundaries or size of the field 100 may be used as an input to generate the geospatial CI map. Additionally, other types of field-related data 116 may be collected and used in accordance with aspects of the present subject matter, such as crop rotation data, historical field data, and/or the like.

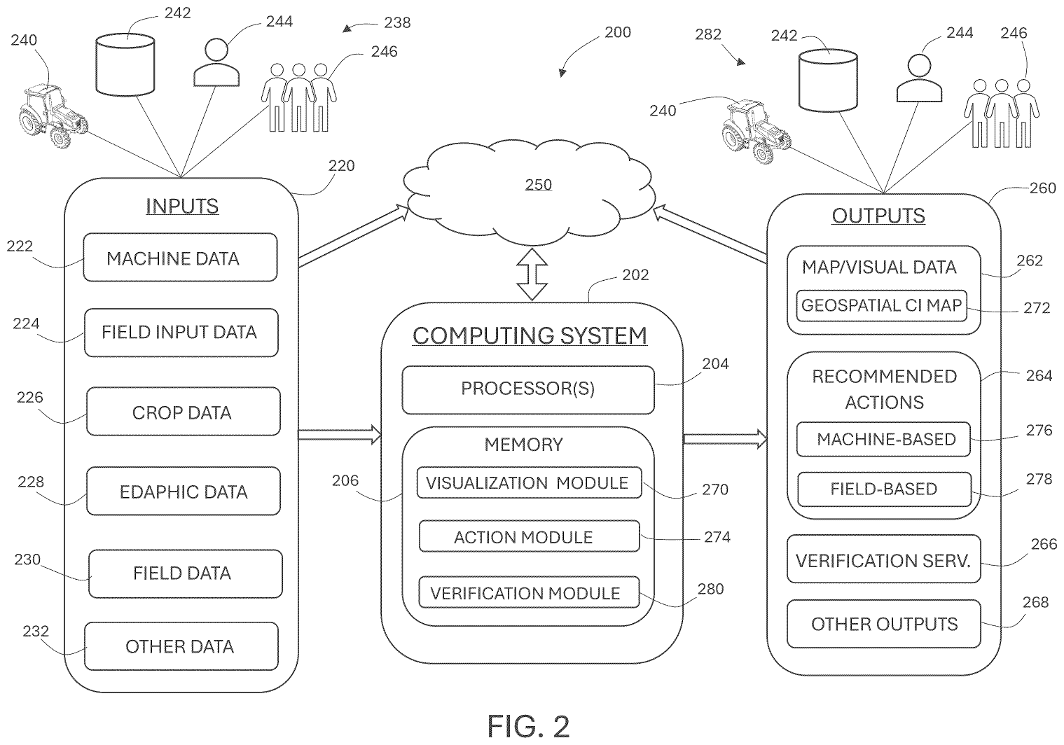

Referring now to FIG. 2, a schematic view of one embodiment of a system 200 for generating geo-referenced agricultural maps and/or for planning/managing agricultural operations based on such maps is illustrated in accordance with aspects of the present subject matter. For purposes of discussion, the system 200 shown in FIG. 2 will be primarily described with reference to the generation and use of geospatial CI maps and, thus, the system 200 may be adapted to use any and/or all of the various types/sources of data described above with reference to FIG. 1. However, as indicated above, the disclosed system 100 may also be utilized to generate/use various other types of geo-referenced agricultural maps. Thus, it should be appreciated that the disclosed system 100 need not be limited to applications involving geospatial CI maps and/or other CI-related features/functionality.

As shown in FIG. 2, the system 200 may include a computing system 202. In general, the computing system 202 may comprise one or more processor-based devices, such as a given computing device or any suitable combination of computing devices. Thus, in several embodiments, the computing system 202 may include one or more processor(s) 204 and associated memory device(s) 206 configured to perform a variety of computer-implemented functions. As used herein, the term “processor” refers not only to integrated circuits referred to in the art as being included in a computer, but also refers to a controller, a microcontroller, a microcomputer, a programmable logic circuit (PLC), an application specific integrated circuit, and other programmable circuits. Additionally, the memory device(s) 206 of the computing system 206 may generally comprise memory element(s) including, but not limited to, a computer readable medium (e.g., random access memory RAM)), a computer readable non-volatile medium (e.g., a flash memory), a floppy disk, a compact disk-read only memory (CD-ROM), a magneto-optical disk (MOD), a digital versatile disk (DVD) and/or other suitable memory elements. Such memory device(s) 206 may generally be configured to store suitable computer-readable instructions that, when implemented by the processor(s) 202, configure the computing system 202 to perform various computer-implemented functions, such as one or more aspects of the methods described herein. In addition, the computing system 202 may also include various other suitable components, such as a communications circuit or module, one or more input/output channels, a data/control bus and/or the like.

It should be appreciated that the various functions of the computing system 202 may be performed by a single processor-based device or may be distributed across any number of processor-based devices, in which instance such devices may be considered to form part of the computing system 202. For instance, the functions of the computing system 202 may be distributed across multiple computing devices (including multiple application-specific controllers or computing devices) that can be positioned locally or remote relative to one another. As an example, the vehicle controller of an agricultural machine may form all or part of the computing system 202.

As shown in FIG. 2, the computing system 202 may be configured to receive various different types of input data 220. For instance, in the illustrated embodiment, the computing system 202 is configured to receive input data 202 including, but not limited to, machine data 222, field input data 224, crop data 226, edaphic data 228, field data 230, and any other suitable input data (indicated by “other data 232” in FIG. 2). As will be described in greater detail below, the input data 220 may allow the computing system 202 to generate maps and other visual data (including geospatial CI maps), determine recommendations regarding actions to be taken in terms of the planning, management, and/or execution of agricultural operations, and/or provide verification services for system users (including producers and downstream consumers) for verifying output data generated by the computing system 202 (including CI scores). In this regard, it should be appreciated that, in several embodiments, the input data 220 may, for instance, correspond or relate to a given field or set of fields to allow field-specific maps/data, recommended actions, and/or verification services to be generated/provided by the system 100.

Machine data 222 may generally include data associated with the operation of machines associated with the production of crops during an applicable crop production cycle (e.g., including data 104 described above with reference to FIG. 1), including in-field machines used to perform agricultural operations and other machines used to support in-field operations, such as such tractors, combine harvesters, self-propelled sprayers, fertilizer applicators, grain trucks, transport vehicles, service/utility vehicles, pickups, aerial vehicles, etc. As one non-limiting example, machine data 222 may include, but is not limited to, fuel data (e.g., fuel consumption data), other energy-related input data (e.g., electricity inputs), machine identification data (e.g., VIN numbers), time-related machine data (e.g., hours of operation), historical machine data, and/or any other suitable machine data. For instance, machine data 222 may include any suitable energy-related data (e.g., fuel data, electricity or power data, precision farming performance data, tractive efficiency data, combine threshing efficiency data, etc.) collected in relation to the performance of tillage, fertilizer application, planting, spraying, seeding, irrigation, harvesting, and/or the like. In one embodiment, all or portions of the machine data 222 may be geo-referenced (e.g., by tagging the data with corresponding GPS coordinates or other position data) to allow the data to be correlated to specific locations within a field.

Field input data 224 may generally include data associated with the various inputs within a field across an applicable crop production cycle (e.g., including data 106 described above with reference to FIG. 1), including input applied to or integrated within the field and/or any other suitable inputs (e.g. as-applied or crop inputs, edaphic-related inputs, ephemeral-related inputs, etc.). As one non-limiting example, field input data 224 may include, but is not limited to, tillage data (e.g., including the type of tillage performed), as-applied input rates/amounts (such as input rates/amounts for manure, seeds, lime, fertilizer (macro/micro, chelates), herbicides, inoculants, insecticides, other protection chemicals, and/or the like), ephemeral-related inputs (e.g., weather data) historical field input data, carbon inputs associated with the production in field inputs (e.g., fertilizer production), crop cover data, and/or any other suitable field input data. In one embodiment, all or portions of the field input data 224 may be geo-referenced (e.g., by tagging the data with corresponding GPS coordinates or other position data) to allow the data to be correlated to specific locations within a field.

Crop data 226 (or harvesting data) may generally include data associated with the crops harvested up to and at the end of the applicable crop production cycle (e.g., including data 108 described above with reference to FIG. 1). As one non-limiting example, crop data 226 may include, but is not limited to, yield data, moisture data, NDVI data, crop constituent data (e.g., protein percentage, oil percentage, starch percentage, etc.), harvester-based data, historical crop data, and/or any other suitable crop data. In one embodiment, all or portions of the crop data 226 may be geo-referenced (e.g., by tagging the data with corresponding GPS coordinates or other position data) to allow the data to be correlated to specific locations within a field.

Edaphic data 228 may generally include data associated with the soil within the associated field (e.g., including data 110 described above with reference to FIG. 1). As one non-limiting example, edaphic data 228 may include, but is not limited to, soil carbon data (e.g., the total carbon content and/or the amounts of inorganic carbon, organic carbon, biologically active carbon, mineral-associated carbon, and/or the like), soil type, soil texture data, soil fertility data (e.g., a total amount of Nitrogen or available amounts of phosphorus, potassium and/or other soil constituents), surface drainage data, non-carbon soil constituent data, pH levels, and/or any other suitable soil or edaphic data. In one embodiment, all or portions of the edaphic data 228 may be geo-referenced (e.g., by tagging the data with corresponding GPS coordinates or other position data) to allow the data to be correlated to specific locations within a field.

Field data 230 may generally include data associated with the applicable field (e.g., including data 116 described above with reference to FIG. 1). As one non-limiting example, field data 230 may include, but is not limited to, size/boundary data, crop rotation data, historical field data, and/or any other suitable field data. In one embodiment, all or portions of the field data 230 may be geo-referenced (e.g., by tagging the data with corresponding GPS coordinates or other position data) to allow the data to be correlated to specific locations within or along boundaries of a field.

Other data 232 may generally include any other suitable type of data that may be used by the system 100 when performing the functions and/or providing the output data described herein. As one non-limiting example, other data 232 may include, but is not limited to, user preferences and settings, jurisdiction-specific protocols or protocol data and/or any other suitable data. For instance, as described above, protocol data associated with jurisdiction-specific protocols for calculating CI scores may be transmitted to and/or accessible by the computing system 202 for allowing CI scores to be calculated (and corresponding CI maps to be generated) in accordance with such jurisdiction-specific protocols. In one embodiment, all or portions of any other data 232 used by the system may be geo-referenced (e.g., by tagging the data with corresponding GPS coordinates or other position data) to allow the data to be correlated to specific locations within or along boundaries of a field.

It should be appreciated that the various types of input data 220 may derive from any number and/or type of data sources 238. For instance, as shown in FIG. 2, data sources 238 may include, but are not limited to, machines 240 (such as tractors, combine harvesters, self-propelled sprayers, fertilizer applicators, grain trucks, transport vehicles, service/utility vehicles, pickups, etc., (including machines 102 described above with reference to FIG. 1) and including sensors located on or otherwise associated with such machines), databases 242 (e.g., including databases local and/or remote to the computing system 202), system users 244 (e.g., crop producers, downstream consumers etc.), third-party service providers 246 (e.g., soil testing service providers, etc.), and/or the like.

It should also be appreciated that the input data 220 may be transmitted to and/or received by the computing system 202 using any suitable communication and/or transmission means/method. For instance, in several embodiments, all or portions of the input data 220 may be received directly from a given data source 238, such as through a physical or wired connection with the data source 238. In addition (or as an alternative thereto), all or portions of the input data 220 may be received from a given data source 238 via an associated network 250, including any suitable wired or wireless network. In general, the network 250 can be any type of network or combination of networks that allows for communication between devices, including between the computing system and any suitable data source. In some embodiments, the network 350 can include one or more of a local area network, wide area network, the Internet, secure network, cellular network, mesh network, peer-to-peer communication link and/or some combination thereof and can include any number of wired or wireless links. Communication over the network 350 can be accomplished, for instance, via a communications interface using any type of protocol, protection scheme, encoding, format, packaging, etc.

As indicated above, in several embodiments, the computing system 202 may be configured to utilize the input data 220 to perform one or more functions, such as by using the data 220 to: (1) generate maps and other output data (including geospatial CI maps); (2) determine recommendations regarding actions to be taken in terms of the planning, management, and/or execution of agricultural operations; and/or (3) provide verification services for system users (including producers and downstream consumers) for verifying output data generated by the computing system 202 (including CI scores). In this regard, in several embodiments, the instructions stored within the memory 206 of the computing system 202 may be executed by the processor(s) 204 to implement one or more software modules configured to provide one or more outputs 260. As an example, outputs 260 of the computing system 202 may include map/visual data 262, recommendations or recommended actions 264, verification services 266, and/or any other suitable output data 268.

As shown in FIG. 2, in several embodiments, the instructions stored within the memory 206 of the computing device 202 may be executed by the processor(s) 204 to implement a visualization module 270. In general, the visualization module 270 may be configured to generate visual-type data for use/analysis by system users and/or others, including mapping data and/or other visual data. In this regard, the visualization module 270 may be configured to receive/analyze the input data 220 to allow for various types of visual data to be generated. For instance, as indicated above, all or portions of the input data 220 may be geo-referenced, thereby allowing the visualization module to generate geo-referenced agricultural maps incorporating such data.

In several embodiments, the visualization module 270 may be configured to generate a geospatial CI map 272. For instance, utilizing the relevant machine data 222, field input data 224, crop data 226, edaphic data 228, field data 230, and/or any other suitable data 232 associated with a given field, the visualization module 270 may generate a geospatial CI map that correlates a CI score to every location (or various locations) across the field. Specifically, the geo-referenced input data 220 may be used by the visualization model 270 to calculate a CI score at each location (or at various locations) across the field, which can then be mapped in any suitable format for presentation or viewing.

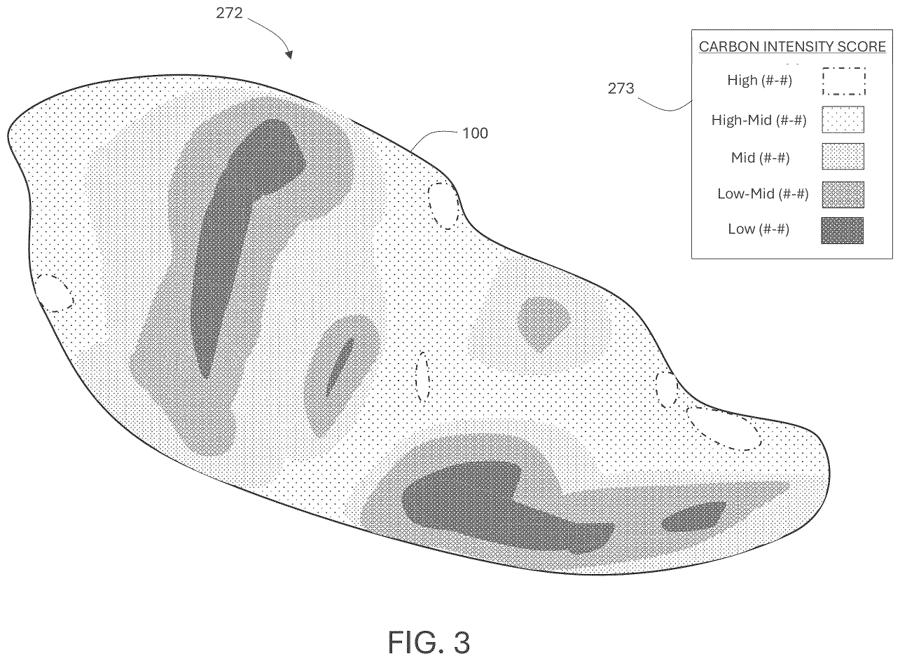

For example, FIG. 3 illustrates an exemplary geospatial CI map 272 for the field 100 shown in FIG. 1. As shown, the CI map 272 is visualized or represented as a heatmap or similar type of map that correlates different colors/patterns/fills to a given CI score or range, such as by providing different colors/patterns/fills across the map 272 to represent one of various CI score ranges (e.g., as indicated in legend 273 a high CI score range, a high-mid CI score range, a mid CI score range, a low-mid CI score range, and a low CI score range). As such, a viewer of the CI map 272 may be able to quickly assess the variations in CI scores across the field. However, in general, it should be appreciated that the geospatial CI map 272 may have any suitable format and/or may include any suitable content, including by being presented in the form of any other suitable type of map. In this regard, a suitable geospatial CI map 272 may include any suitable data format that correlates CI scores or other CI-related data to geographic locations within a field, including a simple data table correlating such data/locations and/or any suitable map-type visualization. It should be appreciated that the CI scores contained within the map 272 (or otherwise generated by the computing system 202 or included as data to compile the CI map) may be used as an input (e.g., a direct or indirect input) into any suitable vehicle or machine control system for controlling the operation of the associated machine.

Referring back to FIG. 2, the visualization module 270 may also be configured to generate any other suitable maps or visual data. For instance, based on the edaphic data 228 associated with the field, the visualization module 270 may generate one or more field carbon maps that geo-reference carbon-related data to each or various locations within the field, such as a general carbon content map, an organic matter content map, an inorganic matter content map, and/or the like. Similarly, based on field input data 224, the visualization module 270 may generate one or more as-applied field input maps that geo-reference one or more types of as-applied field inputs to each (or various locations) within the field. For instance, as-applied field input maps may include, but are not limited to, seeding/planting maps, tillage maps, fertilizer maps, seeding maps, and/or the like. Similarly, the visualization module 270 may generate one or more other field input maps that geo-reference one or more other types of field inputs to each (or various locations) within the field, such as crop input maps. As yet another example, the visualization module 270 may generate one or more fertilizer usage efficiency maps. For instance, based on field input data 224 and crop data 226, the computing system 202 may determine the amount of nitrogen that was applied to the field (e.g., in the form of fertilizer) and the amount of nitrogen that was contained within the harvested crops (e.g., by calculating the crop-related nitrogen based on the percentage of protein within the crop, which is directly related to the amount of nitrogen therein). In such instance, the visualization module 270 may be configured to calculate the usage efficiency of nitrogen at each (or various) locations across the field. Moreover, by capturing edaphic data 228 post-harvesting, a determination may also be made regarding the proportions of unused nitrogen that remain within the field versus the nitrogen that was lost to other means (e.g., runoff).

Additionally, as shown in FIG. 2, the instructions stored within the memory 206 of the computing device 202 may also be executed by the processor(s) 206 to implement a strategy/recommendation or “action” module 274. In general, the action module 274 may be configured to analyze the input data 220 to provide recommended or executable actions for improving the overall field performance, such as by providing recommended or executable actions for improving the biological and/or economic response within the field to reduce the CI score across all or one or more portions of the field. For instance, the action module 274 may be configured to automatically generate field prescriptions (e.g., tillage prescriptions, seeding prescriptions, spraying prescriptions, fertilizing prescriptions, etc.) and/or generate other control actions or suggestions to allow for targeted CI management or to optimize other field-related parameters (e.g., fertilizer usage efficiency). In addition, the action module 274 may also be configured to generate recommended actions for maximizing the profitability of the harvested crops, such as by providing suggestions for crop segmentation, crop blending, and/or the like.

As shown in FIG. 2, in one embodiment, the recommended or executable actions provided by the computing system 202 may correspond to machine-based actions 276. Such actions may generally correspond to machine-related improvements, adjustments, and/or the like for improving the overall performance within the field. For instance, machine-based actions 276 may include adjustments to specific machine settings, setting-specific prescriptions when performing an agricultural operation within the field, recommendations for improvements or upgrades to be made to a machine (e.g., suggestions to update to an automated add-on feature, such as smart tillage features, smart planting features, smart spraying features, smart harvesting features, etc.), and/or recommendations for new machines that can enhance the performance within the field. For instance, prescription data, such as tillage depth prescriptions, sprayer rate prescriptions, fertilizer rate prescriptions (e.g., nitrogen rate prescriptions), and/or the like may be generated for use when processing the field during the next crop production cycle. As another example, recommendations may be provided for reducing the fuel consumption of the machine(s) being used within the field (e.g., by providing route-planning guidance or other guidance-related data) or the deployment or engagement of advanced machine operational optimization techniques (e.g., advanced software and related systems, including for instance, combine threshing efficiency software and digital crop residue management subsystems), thereby allowing for a reduction in the related CI score.

Moreover, as shown in FIG. 2, the recommended or executable actions provided by the computing system 202 may correspond to field-based actions 278. Such actions may generally correspond to field-directed actions that can be taken to improve the overall performance within the field. For instance, field-based actions 278 may include suggestions for performing certain types of tillage within the field, for planting cover crop in given areas across the field, and/or the like.

It should be appreciated that, in other embodiments the action module 274 may be configured to provide any other suitable actions, including non-machine-based and/or non-field-based actions.

Additionally, it should be appreciated that, when generating recommended actions or management plans, the computing system 202 may, in several embodiments, be configured to analyze the geospatial CI map and/or any other data accessible to the computing system 202 (including any underlying data used to generate the map) to identify or select specific subsections or “areas of interest” (AOIs) within the field for management. For instance, based on the geospatial CI map and/or any other suitable data, the computing system 202 may identify one or more AOIs within the field and generate a specific action or set of actions (or generally a management plan) for improving the CI score(s) within such area(s) of the field and/or for generally improving the crop performance within such area(s) of the field.

Referring still to FIG. 2, the instructions stored within the memory 206 of the computing device 202 may be executed by the processor(s) 204 to implement a verification module 280. In general, the verification module 280 may be configured to analyze, consolidate, aggregate, or otherwise process the input data 220 received by the computing system 202 and/or the output data 260 generated by the computing system 202 to allow such data to be made available for purposes of providing verification-related services to system users and/or other third-parties. For instance, the verification module 280 may be configured to aggregate or otherwise process the input/output data in a manner that allows for the crop producer to quickly and efficiently verify certain data generated by the computing system 202, such as by allowing the producer to view the various data layers incorporated into the calculation of the CI scores included within the geospatial CI map 272. Additionally, the verification module may be configured to make such data available to downstream consumers of the crops provided by the producer, such as by making the data available via a digital ledger (e.g., private ledger blockchain or public ledger) to allow such consumers to independently verify the CI scores or other data provided by the producer (and/or the system 200).

It should be appreciated that, in accordance with aspects of the present subject matter, the computing system 202 may be configured to tag or associate the harvested crops from specific locations within the field with the CI scores or other data deriving from such specific locations within the field. By linking or associating crops with their specific CI scores (or other underlying data), such information can be used by a producer for subsequent blending of the crops (e.g., on a CI-related basis), for marketing purposes, and/or for overall participation in the value chain. In other words, the geo-referenced nature of the data described herein may allow for a producer to selectively monetize their crops, if desired (e.g., within tax programs, according to ethanol standards, or using any other value-add-related systems or mechanisms).

It should also be appreciated that the outputs 260 generated by the computing system 202 may be communicated or transmitted (e.g., via the network 250) to any suitable data/service consumers 282, including one or more machines 240, databases 242, system users 244, third-party service providers 246, and/or the like. For instance, map/visual data 262 may be generated for presentation to system users 244 and/or third-party service providers 246 (e.g., agronomists and/or downstream consumers) for analyzing the data for purposes of planning/managing agricultural operations within the field and/or as part of any verification services being utilized. Similarly, action-related data 264 may be communicated to system users 244 to allow such users to make informed decisions regarding any suitable machine-based, field-based, or other suitable actions that may be executed to improve the performance within the field. In addition (or as an alternative), the action-related data 264 may be transmitted directly to machines 240 with instructions to automatically execute suitable control actions, such as field prescriptions, setting adjustments, and/or any other suitable machine-based actions. In this regard, the computing system 202 may, in certain embodiments, be configured to initiate the automatic execution of control actions by a given machine(s) 240.

As an example, outputs 260 generated by the computing system 260 may be transmitted to or linked with any suitable vehicle or machine control system for a machine 240 performing operations within the field. As such, the outputs may be used directly by the machine control system to automate or control the operation of the machine 240. For instance, the maps/data received at the machine control system may be used for improved machine operational efficiency, performance optimization, machine settings, and/or adjustments.

It should also be appreciated that input data 220 received by the computing system 202 and/or output data 260 generated by the computing system 202 may be stored locally by the computing system 202 or may be accessible via one or more memory device(s) that are remote from the computing system 202. For instance, input/output data may be remotely accessed by the computing system 202 via the network 250.

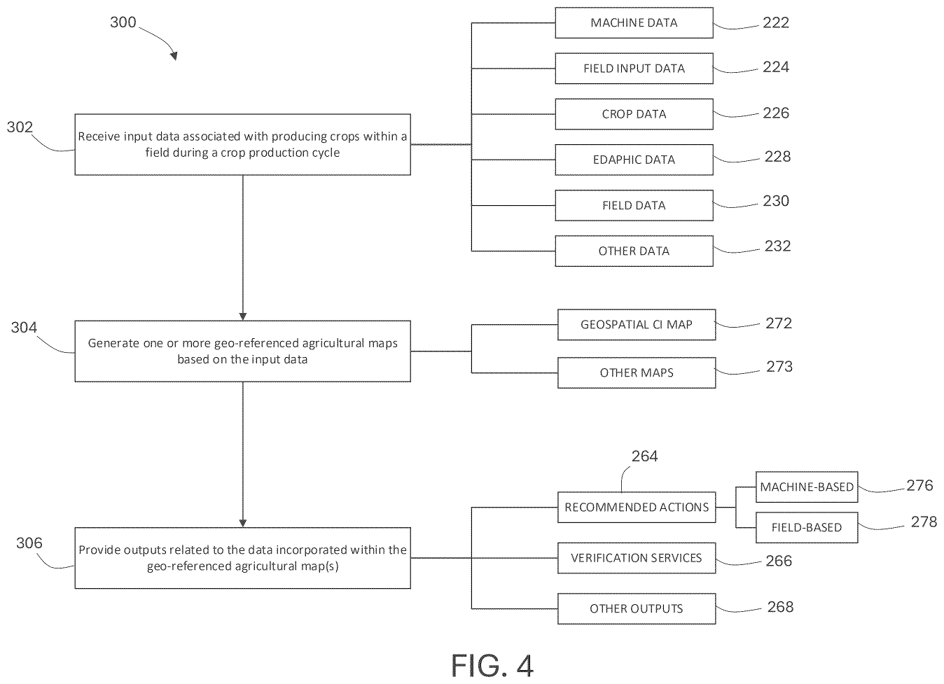

Referring now to FIG. 4, a flow diagram of one embodiment of a method 300 for generating geo-referenced agricultural maps and/or for planning/managing agricultural operations based on such maps is illustrated in accordance with aspects of the present subject matter. In general, the method 300 will be described herein with reference to the system 200 described above with reference to FIG. 2. However, it should be appreciated by those of ordinary skill in the art that the disclosed method 300 may generally be implemented within any system having any suitable system configuration. In addition, although FIG. 4 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present disclosure.

As shown in FIG. 4, at (302), the method 300 includes receiving input data associated with producing crops within a field during a crop production cycle. For instance, as indicated above, the computing system 202 may be configured to receive input data 220 from one or more data sources 238. As an example, input data 220 may include machine data 222, field input data 224, crop data 226, edaphic data 228, field data 230, and/or any other suitable data 232.

Additionally, at (304), the method 300 includes generating one or more geo-referenced agricultural maps based on the input data. For instance, as indicated above, the computing system 202 may be configured to analyze the input data 220 and subsequently generate one or more geo-referenced agricultural maps, such as a geospatial CI map 272 or any other suitable maps 273. For instance, other geo-referenced maps 273 may include carbon maps, field input maps, fertilizer usage efficiency maps, and/or various other maps.

Moreover, at (306) the method 300 includes providing outputs related to the data incorporated within the geo-referenced agricultural map(s). For instance, as indicated above, the computing system 202 may be configured to provide outputs associated with the planning or management of future agricultural operations, such as by providing recommended actions 264 for adjusting machine-related operations (e.g., machine-based actions 276) and/or for adjusting field-related operations (e.g., field-based actions 278). In addition, the computing system 202 may be configured to provide outputs associated with the provision of verification services 266, such as by making the geo-referenced map(s) and/or related data available within a given ledger for access by producers, downstream consumers, third-party service providers, and/or the like. Moreover, the computing system 202 may also be configured to provide any other suitable outputs 268 for use by system users and/or the like.

It is to be understood that the steps of the method 300 are performed by the computing system 202 upon loading and executing software code or instructions which are tangibly stored on a tangible computer readable medium, such as on a magnetic medium, e.g., a computer hard drive, an optical medium, e.g., an optical disc, solid-state memory, e.g., flash memory, or other storage media known in the art. Thus, any of the functionality performed by the computing system 202 described herein, such as the method 300, is implemented in software code or instructions which are tangibly stored on a tangible computer readable medium. The computing system 202 loads the software code or instructions via a direct interface with the computer readable medium or via a wired and/or wireless network. Upon loading and executing such software code or instructions by the computing system 202, the computing system 202 may perform any of the functionality of the computing system 202 described herein, including any steps of the method 300 described herein.

The term “software code” or “code” used herein refers to any instructions or set of instructions that influence the operation of a computer or controller. They may exist in a computer-executable form, such as machine code, which is the set of instructions and data directly executed by a computer's central processing unit or by a controller, a human-understandable form, such as source code, which may be compiled in order to be executed by a computer's central processing unit or by a controller, or an intermediate form, such as object code, which is produced by a compiler. As used herein, the term “software code” or “code” also includes any human-understandable computer instructions or set of instructions, e.g., a script, that may be executed on the fly with the aid of an interpreter executed by a computer's central processing unit or by a controller.

This written description uses examples to disclose the technology, including the best mode, and also to enable any person skilled in the art to practice the technology, including making and using any devices or systems and performing any incorporated methods. The patentable scope of the technology is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

1. An agricultural system, comprising:
a computing system including a processor and memory, the memory storing instructions that, when implemented by the processor, configure the computing system to:
receive input data associated with producing crops within a field during a crop production cycle;
calculate carbon intensity (CI) scores for a plurality of locations within the field based at least in part on the input data; and
generate a geospatial CI map based on the calculated CI scores.

2. The system of claim 1, wherein the computing system is further configured to generate recommended control actions based on the geospatial CI map.

3. The system of claim 2, wherein the recommended control actions comprise control actions for optimizing machine operations.

4. The system of claim 1, wherein the computing system is further configured to provide verification services for assessing the CI scores included in the geospatial CI map.

5. The system of claim 1, wherein the computing system is further configured to identify one or more areas of interest within the field for management based on the geospatial CI map or based on the input data used to generate the geospatial CI map.

6. The system of claim 1, wherein the computing system is further configured to associate the crops harvested from different portions of the field with the corresponding CI scores calculated for such different portions of the field.

7. The system of claim 1, wherein the input data comprises at least one of:
field data associated with a size or boundaries of a field;
machine data associated with machine operations during the crop production cycle within the field, the machine operations occurring at least partially within the field;
field input data associated with inputs within the field during the crop production cycle;
edaphic data associated with soil within the field; or
crop data associated with crops harvested up to and at an end of the crop production cycle.

8. The system of claim 1, wherein the input data comprises field data associated with a size or boundaries of a field, machine data associated with machine operations during the crop production cycle within the field, field input data associated with inputs within the field during the crop production cycle, edaphic data associated with soil within the field, and crop data associated with crops harvested up to and at an end of the crop production cycle.

9. The system of claim 1, wherein the computing system is further configured to access jurisdiction-specific protocol data associated with the calculation of the CI scores.

10. The system of claim 9, wherein the computing system is configured to select the input data for calculating the CI scores based on the jurisdiction-specific protocol data.

11. A method for generating geospatial carbon intensity (CI) maps for fields, the method comprising:
receiving, a computing system, input data associated with producing crops within a field during a crop production cycle;
calculating, with the computing system, carbon intensity (CI) scores for a plurality of locations within the field based at least in part on the input data; and
generating, with the computing system, a geospatial CI map based on the calculated CI scores.

12. The method claim 11, further comprising generating, with the computing system, recommended control actions based on the geospatial CI map.

13. The method of claim 12, wherein the recommended control actions comprise control actions for optimizing machine operations.

14. The method of claim 11, further comprising providing, with the computing system, verification services for assessing the CI scores included in the geospatial CI map.

15. The method of claim 11, further comprising identifying, with the computing system, one or more areas of interest within the field for management based on the geospatial CI map or based on the input data used to generate the geospatial CI map.

16. The method of claim 11, further comprising associating, with the computing system, the crops harvested from different portions of the field with the corresponding CI scores calculated for such different portions of the field.

17. The method of claim 11, wherein receiving the input data comprises receiving at least one of:
field data associated with a size or boundaries of a field;
machine data associated with machine operations during the crop production cycle within the field, the machine operations occurring at least partially within the field;
field input data associated with inputs within the field during the crop production cycle;
edaphic data associated with soil within the field; or
crop data associated with crops harvested up to and at an end of the crop production cycle.

18. The method of claim 11, wherein receiving the input data comprises receiving:
field data associated with a size or boundaries of a field;
machine data associated with machine operations during the crop production cycle within the field, the machine operations occurring at least partially within the field;
field input data associated with inputs within the field during the crop production cycle;
edaphic data associated with soil within the field; or
crop data associated with crops harvested up to and at an end of the crop production cycle.

19. The method of claim 11, further comprising accessing, with the computing system, jurisdiction-specific protocol data associated with the calculation of the CI scores.

20. The method of claim 19, further comprising selecting, with the computing system, input data for calculating the CI scores based on the jurisdiction-specific protocol data.
